(19) United States
(12) Patent Application Publication
(10) Pub. No.: US 2011/0204386 A1
(43) Pub. Date: Aug. 25, 2011

(54) METAL BASED ELECTRONIC COMPONENT PACKAGE AND THE METHOD OF MANUFACTURING THE SAME

(75) Inventors: Dani Alon, Providence, RI (US); Clark L. Smith, Columbus, NE (US); Todd L. Wyatt, Columbus, NE (US); Rodney J. Brune, Columbus, NE (US); Mustafa Dinc, Heilbronn (DE); Norbert Pieper, Selb (DE)

(73) Assignee: VISHAY SPRAGUE, INC., Bennington, VT (US)

(21) Appl. No.: 13/012,960

(22) Filed: Jan. 25, 2011

Related U.S. Application Data
(60) Provisional application No. 61/298,123, filed on Jan. 25, 2010.
(60) Provisional application No. 61/345,746, filed on May 18, 2010.

(51) Int. Cl. H01L 33/08; H01L 23/495

(52) U.S. Cl. 257/88; 438/28; 257/676; 257/E33.005; 257/E23.031

(57) ABSTRACT

A package for an electronic component and method of forming a package for an electronic component are disclosed. The package may include a metal base and a termination chip coupled to the metal base. The termination chip may include a die contact pad electrically coupled to a mounting pad and an isolating feature configured to provide electrical isolation between the metal base and the die contact pad. The contact may be configured for electrical connection to the electronic component. The metal base may be folded to form a molding cavity. The metal base may include at least one plating layer. The package may include a light emitting diode (LED) coupled to the metal base. The LED may be coupled to the metal base via a eutectic bond.

### CROSS REFERENCE TO RELATED APPLICATIONS

This application claims the benefit of U.S. Provisional Application No. 61/298,123, filed Jan. 25, 2010 and U.S. Provisional Application No. 61/345,746, filed May 18, 2010, the contents of which is hereby incorporated by reference herein in their entireties.

### FIELD OF INVENTION

This application is related to electronic component packaging. More particularly, this application is related to semiconductor packaging.

### BACKGROUND

Thermal management is one of the biggest challenges facing designers. Many electronic components can benefit from packaging that allows better thermal performance. For example, light emitting diode (LED) die performance is extremely temperature sensitive. As LED junction temperature increases, LED efficiency drops, the lifetime of the LED is reduced and the overall light flux emitted from the LED declines.

### SUMMARY

A package for an electronic component and method of forming a package for an electronic component are disclosed. The package may include a metal base and a termination chip coupled to the metal base. The termination chip may include a die contact pad electrically coupled to a mounting pad and an isolating feature configured to provide electrical isolation between the metal base and the die contact pad. The contact may be configured for electrical connection to the electronic component.

The metal base may be folded to form a molding cavity. The metal base may be plated or metalized at selected areas. These metallized areas may include a layer of a layer of Ni and a layer of Au. These areas may also include a layers of solder such as Sn.

The package may include a light emitting diode (LED) coupled to the metal base. The LED may be coupled to the metal base via a eutectic bond. The package may include an electrostatic discharge (ESD) protection device coupled to the metal base. The package may include a plurality of angled die planes integrated into the metal base, the angled die planes being configured to mount a plurality of light emitting diodes.

The termination chip may include a plurality of embedded circuit components. The termination chip may include a metallized ceramic substrate configured to provide electrical isolation between the metal base and the plurality of terminations deposited on the termination chip. The termination chip may include a ceramic base and top, bottom and side copper pads configured to be soldered to the metal base. The termination chip may also include a plurality of embedded circuit components.

The package may include a metal base having a first and second terminal. The first terminal may have a die contact pad. The second terminal may have a wire bonding pad. The package may also include a package top configured to locate and secure the terminals. The package top may be formed with a cavity configured to expose the die contact pad and the wire bonding pad. The die contact pad being configured for electrical connection to the electronic component.

The package top may be formed with a raised portion. The metal base may be formed with a slot dimensioned to accept the raised portion. The raised portion may electrically isolate the first and second terminals. The metal base may include at least one plating layer. The metal base may have an upper surface plated with a layer of gold. The metal base may have a lower surface plated with a layer of solder.

The package may include a semiconductor die mounted in the cavity and electrically connected to the die contact pad. The semiconductor die may be a light emitting diode (LED). The LED may be coupled to the metal base via a eutectic bond. The package may include a wire bond electrically connecting at least a portion of the semiconductor die to the wire bonding pad. The package may include an electrostatic discharge (ESD) protection device coupled to the metal base. The package may include a plurality of angled die planes integrated into the metal base, the angled die planes being configured to mount a plurality of light emitting diodes. The package top may be joined to the metal base by at least one of an adhesive and an electrically conductive material. The package top may be molded to the metal base. The package may include a molding material filling the cavity.

### BRIEF DESCRIPTION OF THE DRAWINGS

A more detailed understanding may be had from the following description, given by way of example in conjunction with the accompanying drawings wherein:

FIG. 1 shows a metal base mechanically manipulated to facilitate package fabrication;

FIG. 2 shows a metal base with a first metallized layer to allow die assembly by eutectic bond;

FIG. 3 shows a metal base with a second metallized on the rear to allow package SMT assembly;

FIG. 4 shows a metal base folded to form a molding cavity;

FIGS. 5A and 5B show a termination chip manufactured on a ceramic substrate with two sided Copper on Alumina with a plated via;

FIG. 6 shows a termination chip positioned in an insert cavity;

FIG. 7A shows an individual package are separates from the metal base strip;

FIG. 7B shows an assembled package including die, wire-bonds and encapsulating compound;

FIG. 8 shows a three terminal electronic component mounted in the package;

FIG. 9 shows a metal strip from which terminals are created;

FIG. 10 shows a package body;

FIG. 11 shows several package bodies mounted to a metal strip;

FIG. 12 shows an assembled metal package;

FIG. 13A is a pictorial view of a package with an angled die plane;

FIG. 13B is a side view of a package with an angled die plane;

FIG. 14A is a diagram of a LED installed in a package with a flat die plane;

FIG. 14B is a diagram of an LED install in a package with an angled die plane.

### DETAILED DESCRIPTION

Various packaging technologies can be used to address thermal issues. For example:

1. Packages based on highly thermally conductive ceramic substrates.

2. Packages based on LTCC or molded compounds with metal lead frames. These packages might include a metal heat sink.

3. Packages based on metal-core or metal-backed printed circuit boards.

The following disclosure is directed to the fabrication of electrical components, such as light emitting diodes (LEDs) from metal base strips. The use of such structures is beneficial in the manufacture of electronic component packages with enhanced thermal management.

Important aspects of such structures are:

1. Compared to ceramic alternatives, metal base allows superior thermal conductivity at lower cost.

2. Compared to molded lead frame packages, the metal base allows the use of a eutectic die bond. Molding compounds decompose at high temperature while metal can withstands high temperature. The eutectic die bond is used to achieve lower thermal resistance between the die and the package.

3. The metal based package will allow standard surface mount technology (SMT) assembly. This feature is not possible with Metal-Core or Metal-Backed Printed circuit board alternatives due to the fact that these technologies allow only a single sided design.

4. Alternative packaging technologies conduct heat from the junction (die) to the circuit board. By integrating heat sink fins to the metal base package, the new packaging technology can sink heat directly to ambient, in addition to conventional heat conduction to the circuit board.

5. The metal base package allows the option of creating an angle between the die assembly plane and the package assembly plane. A plurality of light emitting diodes, with differing die planes will result in an improved light radiation pattern. This feature eliminates the need for lenses to achieve the same purpose.

The following is a description of a metal based electronic component package and a method of manufacturing the same by a combination of following manufacturing processes. It is understood that the disclosed manufacturing processes need not be carried out in order. It is also understood that some steps can be combined or omitted.

A metal base compound is selected to optimize the trade off between package features such as cost, thermal conductivity, light reflectance, thermo-mechanical properties, ease of fabrication and electrical properties. In the following example, a copper strip is used.

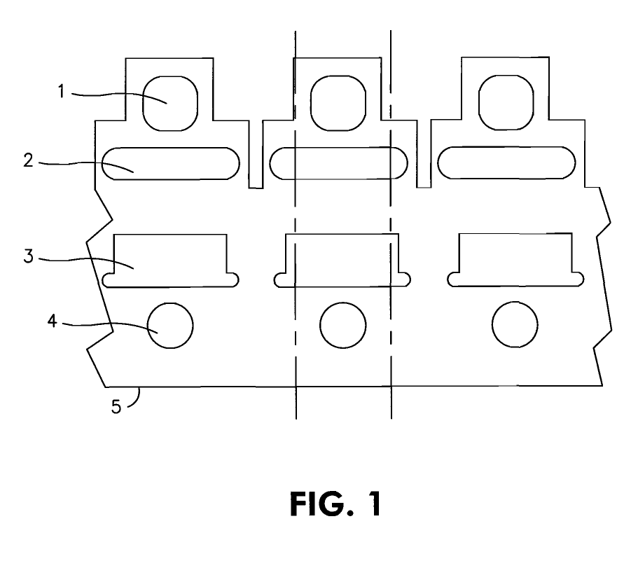

As shown in FIG. 1, a metal base 5 is mechanically manipulated to facilitate package fabrication by means of punching, coining, machining, etching etc. In this embodiment, the metal base 5 is a punched metal strip. The metal base 5 includes a tab formed with a molding cavity window 1, a folding weak spot window 2, a termination cavity 3 and an index hole 4. It is understood that the pattern formed in metal base 5 can be replicated so that multiple devices can be manufactured from a single metal base strip.

The metal base 5 can be mechanically manipulated to feature an angle between the die assembly plane and the package assembly plane.

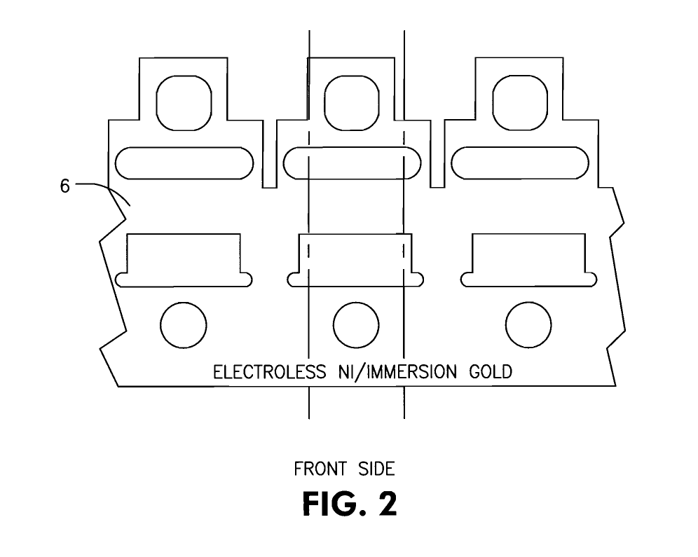

The metal base 5 can be metallized to facilitate package features that might include: SMT package assembly pads, eutectic die attach pads, adhesive die attach pads, bond wire pads, reflective areas, mechanical and chemical protection, esthetic requirements etc. The metallization process can be achieved by one or more techniques such as: sputtering, electro plating, Electroless plating, dipping, screen printing or other paste deposition techniques etc. In the example shown in FIG. 2, the metal base 5 includes a first metal layer 6, formed of electroless plated Ni, immersion plated Au. This layer provides improved bonding for a die attach pad.

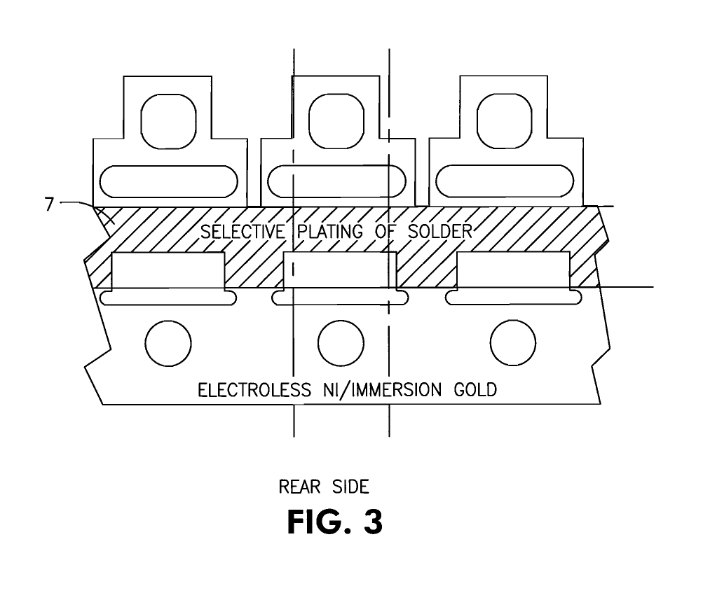

As shown in FIG. 3, a second layer 7 is applied to the rear surface of the metal base 5. In this example, the second layer 7 is a selective plating layer of solder. The second layer 7 provides improved bonding for SMT terminations.

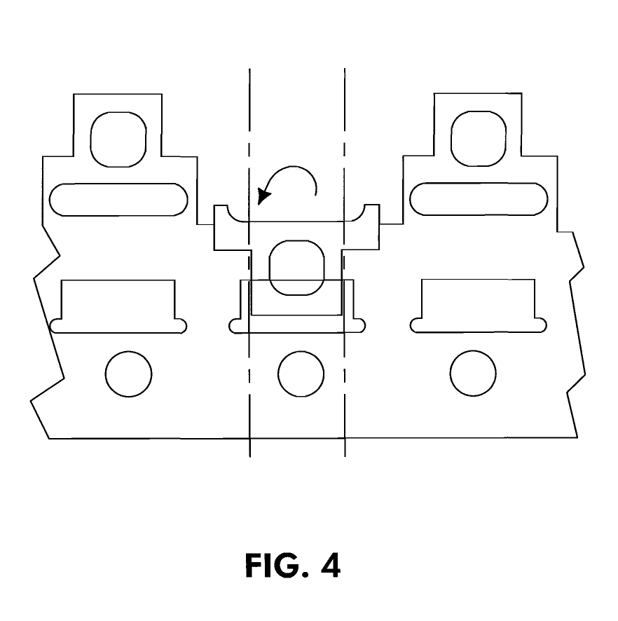

FIG. 4 shows the metal base strip 5 folded along the weak spot window 2. Such folding operations can provide a stacking function and help create features such as: a molding cavity, light reflecting surfaces and/or heat sinking fins. In this example, a molding cavity is formed by folding down the tab formed with molding cavity window 1. A possible alternative would be to form a molding cavity by stacking a separate strip formed with a molding cavity window onto the metal base.

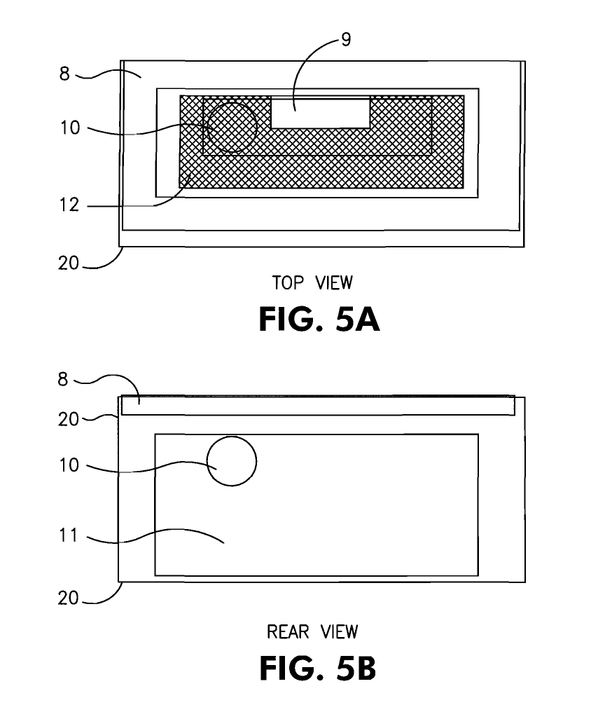

FIGS. 5A and 5B show the formation of a termination chip 20. The termination chip has at least one top die contact pad and a minimum of one bottom package SMT soldering pad that are electrically connected. The termination chip can optionally include other features that include pads and/or insolating surfaces that serve in package assembly. The termination chip can optionally be made from metal that is kept isolated from the metal based package with the use of an adhesive substance. The termination chip can optionally be made during the mechanical manipulation process as part of the metal strip itself. Other circuit elements can be embedded into the package as part of the termination chip. These elements can include: decoupling capacitors, series fuse elements, current limiting resistors, temperature sensing elements, ESD protection diodes etc. In this example, the termination chip 20 includes a ceramic based chip with a single top die contact pad 9 that is connected with a via 10 to the bottom SMT pad 11. Top, bottom and side copper pads 8 are designed to allow the termination chip to be soldered directly to the metal base. An isolating top coating 12 helps to insure electric isolation between the metal base 5 and the termination pad 20. The same termination chip can, for example, be manufactured on an FR4 substrate using standard PCB manufacturing techniques.

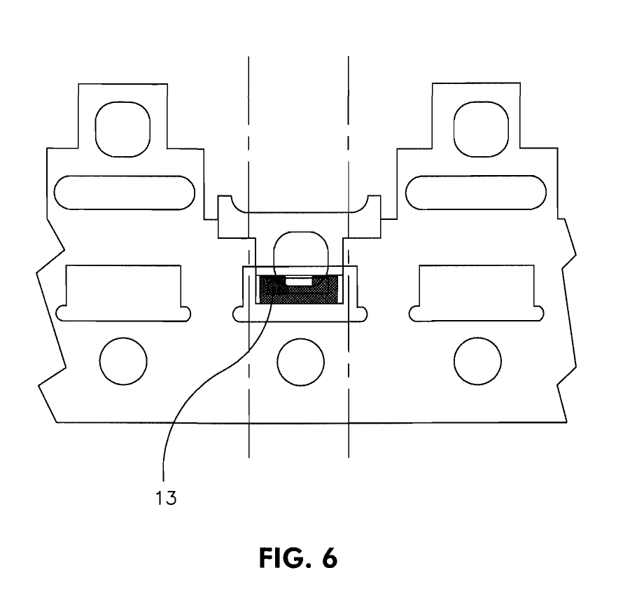

FIG. 6 shows a termination chip 20 inserted into its respective insert cavity 13 in the metal base package. This step can be omitted if the termination chip was made during the mechanical manipulation process that creates the metal base itself. In this example, a single termination chip 20 is used. It is understood that multiple termination chips could be used. A single termination chip can also be formed with multiple electrical contacts or pads.

A connecting mechanism is used to insure package integrity. The connecting mechanism can include one or more of the following techniques such as: mechanical fixturing (pin and socket, clasp etc), adhesives, solders etc. In this example, a solder reflow process is used as the connecting mechanism between the folded metal flap and the termination chip 20.

The termination chip can be utilized for the purpose of embedding desirable circuit elements into the package. These may include single elements or complex networks. Such elements may include resistors, inductors and capacitors as well as fuse element, diodes and/or other devices. Of particular interest is the option to embed elements that can be manipulated to accommodate the characteristics of the packaged device. For example, embedded resistors can be trimmed to compensate for the tolerance of the packaged component.

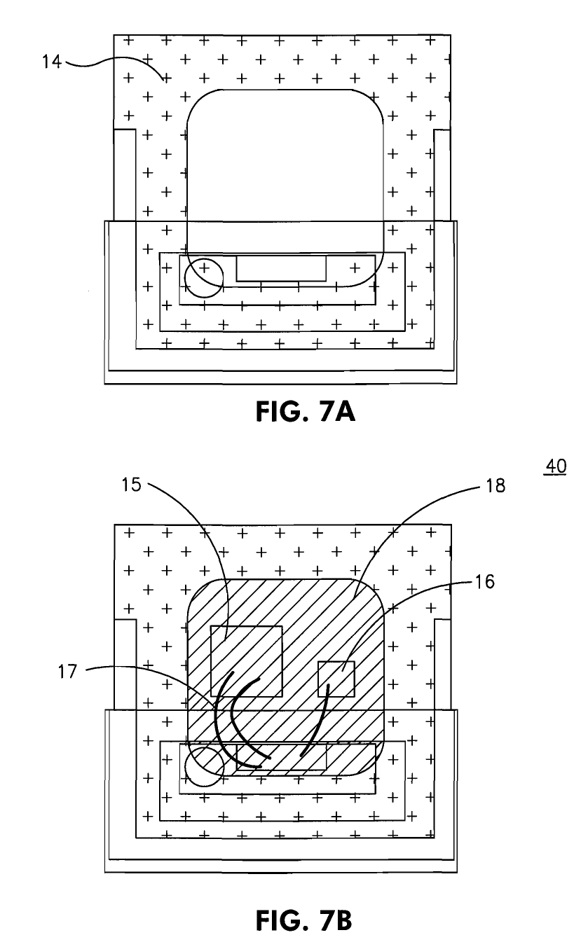

FIG. 7a shows an individual package separated from the metal base 5. Once the package is separated, a metal base package for electronic components is formed. FIG. 7b shows an assembled package 40 including dies (15, 16), wire-bonds (17) and an encapsulating compound (18). In this example, a high power LED 15 and an ESD protection diode 16 are packaged in this technique. Wire bonds (17) are used to provide electric connectivity. The LED 15 and/or ESD protection diode 16 can be attached to the metal base 5 via a eutectic bond. A clear molding compound (18) is finally added to the molding cavity to complete the assembly.

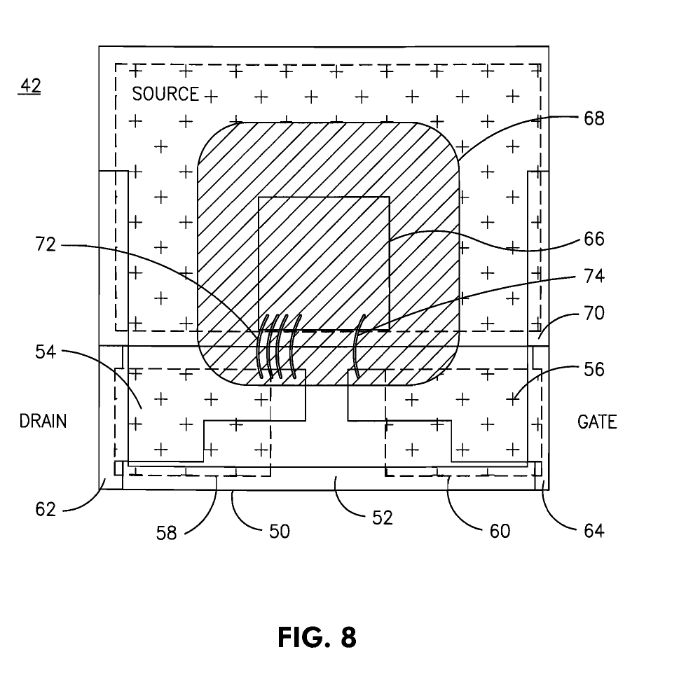

The example shown above is directed to a package for a two terminal electronic component. It should be understood that the package can be used in connection with electronic components having thee or more terminals. FIG. 8 shows a three terminal electronic component mounted in the package 42. In this example, the termination chip 50 is formed with an electrically non-conductive substrate 52, for example ceramic as disclosed above. The top surface of the termination chip has a first die contact pad 54 and a second die contact pad 56. The bottom surface of the termination chip 50 has corresponding first and second mounting pads shown by dashed lines 58, 60. The first die contact pad 54 is electrically connected to the first mounting pad 58 via an electrically conductive side wrap 62. The second die contact pad 56 is electrically connected to the second mounting pad 60 via an electrically conductive side wrap 64. The side wraps 62, 64 can be formed of a variety of materials such as foils and the like. It should also be understood that the electrical connection between the die contact pads and mounting pads can be accomplished with a via as disclosed above.

A three terminal device such as a metal oxide semiconductor (MOS) field effect transistor (FET) 66 is mounted in the molding cavity 68. The body of the MOS FET is coupled to the metal base 70 and functions as the source terminal. Wire bonds 72 electrically couple the MOS FET drain terminal to the first die contact pad 54. Wire bond 74 electrically couple the MOS FET gate terminal to the second die contact pad 56. It should be understood that a wide variety of multi-terminal electronic components can be mounted in the disclosed package without departing from the scope of this disclosure. It should also be understood that techniques other than bond-wires can be used to achieve electric connectivity between the die and the package. For example, the die can be flipped facing down and connected directly to the die contact pads.

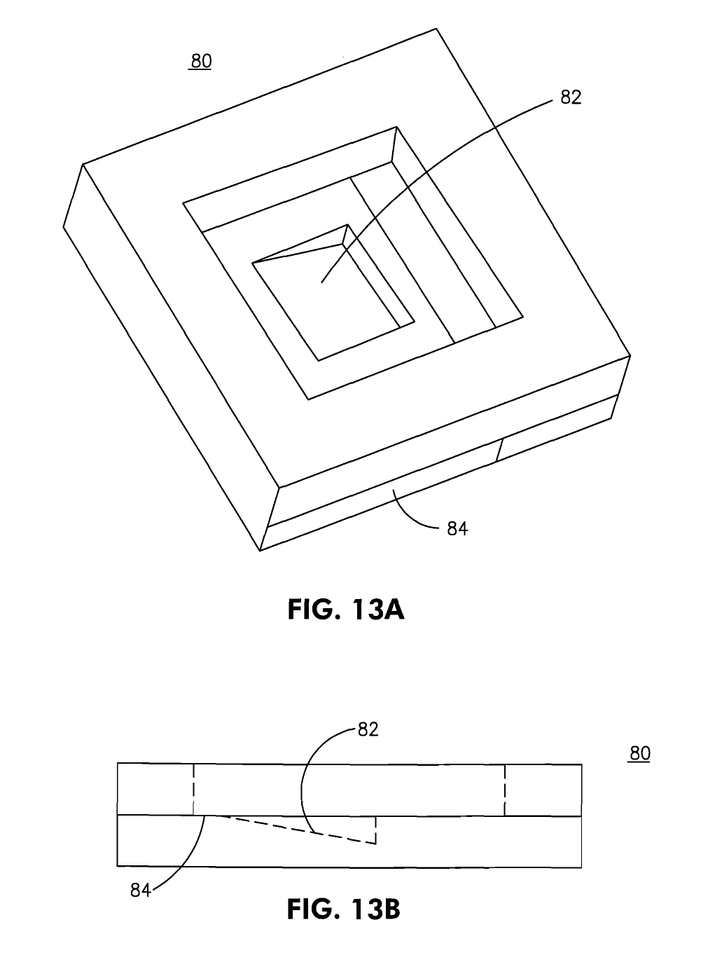

The examples shown above are directed to package structures with a flat surface for mounting the electronic component (e.g., the die is mounted parallel to the mounting surface). In some cases, it may be desirable to provide an angled die mounting plane. FIG. 13a is a pictorial view of a package 80 with an angled die plane 82 with respect to an assembly plane 84. FIG. 13b shows a side view of the package 80 with an angled die plane 82 with respect to the assembly plane 84. The angled die plane can be formed by a variety of methods including stamping, grinding and the like. It is readily apparent that a plurality of angled die planes can be formed in the package 80 without departing from the scope of this disclosure.

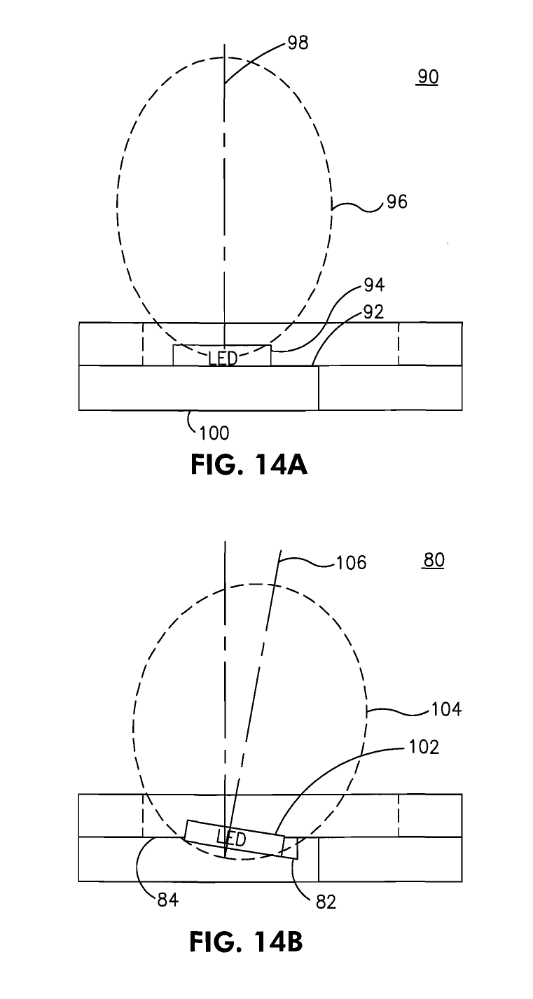

FIG. 14a shows a package 90 with a flat die mounting plane 92. When used with an LED device 94, the LED radiation pattern 96 has an axis 98 that is generally orthogonal to die mounting plane 92 and the metal base 100. FIG. 14b shows a package 80 with an angled die mounting plane 82. When used with an LED device 102, the LED radiation pattern 104 has an axis 106 that is generally orthogonal to die mounting plane 82. This allows the package to generate an angled radiation pattern 104 with respect to the assembly plane 84. It should be understood that a plurality of LEDs can be mounted in such packages and such LEDs can be mounted at a plurality of angles to generate the desired radiation pattern.

In another embodiment, a metal base and ceramic or plastic top can be constructed as follows:

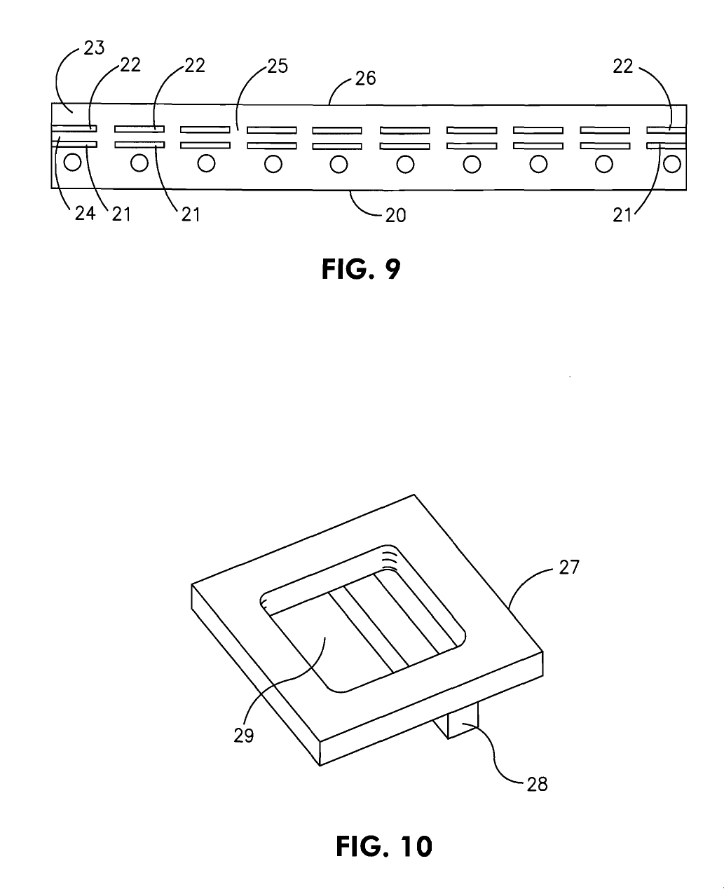

As shown in FIG. 9, a metal strip 20 is punched with slots 21, 22 to separate it into two terminals 23, 24 with tiebars to hold the terminals in place and a carrier strip to facilitate automated processing. The slots 22 are dimensioned to accept a raised portion 28 of a package top 27 (See FIG. 10) to be mated with it in a later step. The metal strip 20 can be any variety of metal. It would be advantageous to select a metal with high thermal and electrical conductivities such as copper or aluminum. The metal strip 20 has an upper surface 25 that will contact the package top and a lower surface 26. The upper surface 25 can be gold plated to facilitate die and wire bonding. The lower surface 26 can be solder coated to facilitate soldering to a PCB.

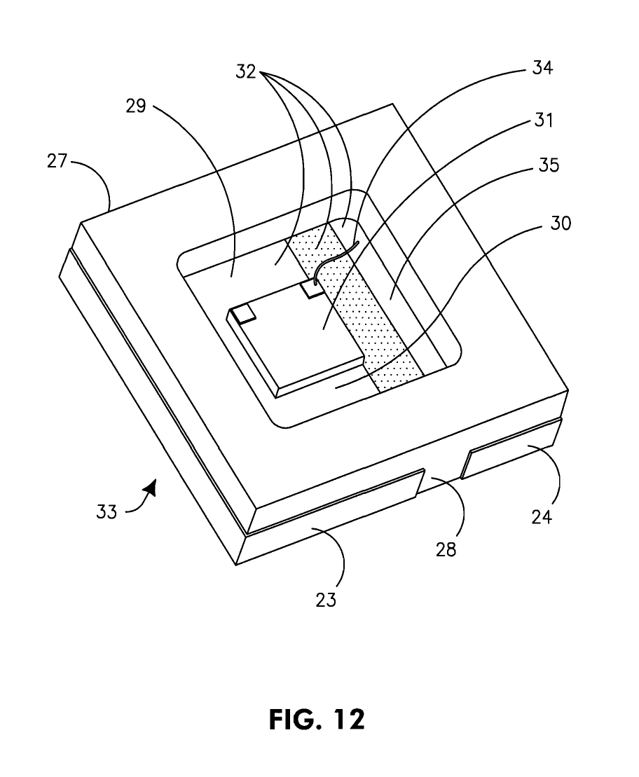

FIG. 10 shows a package top 27 having a geometry that primarily locates and secures the terminals 23, 24. The package top 27 has a raised portion 28 configured to keep the terminals 23, 24 electrically isolated from each other after the tiebar is removed from the leadframe. The raised portion 28 also provides a mechanical connection between the terminals 23, 24 and defines a surface or package floor 32. The package top 27 is formed with a cavity 29 so that a containment area is defined by the cavity 29 and the package floor 32. See FIG. 12. This structure surrounds the semiconductor die and is configured to contain molding material that is deposited after die assembly. The cavity is formed so that portions of terminals 23, 24 are exposed within the cavity 29. An exposed portion of terminal 23 serves as a die contact pad 30. An exposed portion of terminal 24 serves as a wire bonding pad 35. See FIG. 12. The package top 27 may be made of ceramic, plastic, or other rigid materials that are not electrically conductive.

The package top 27 may be joined to the lead frame via an adhesive. The adhesive can be applied to the leadframe in locations corresponding to the contact surfaces of the package top. Another assembly technique is to metalize the terminal side of the package top at the terminal leadframe interface to facilitate soldering during the package assembly process. These metalized areas may be thick film on ceramic or a sputtered seed layer on ceramic or plastic which is then electroplated with nickel and a high temperature solder. In the alternative, the package top 27 may be molded to the leadframe in cases where the package top is formed of a moldable material.

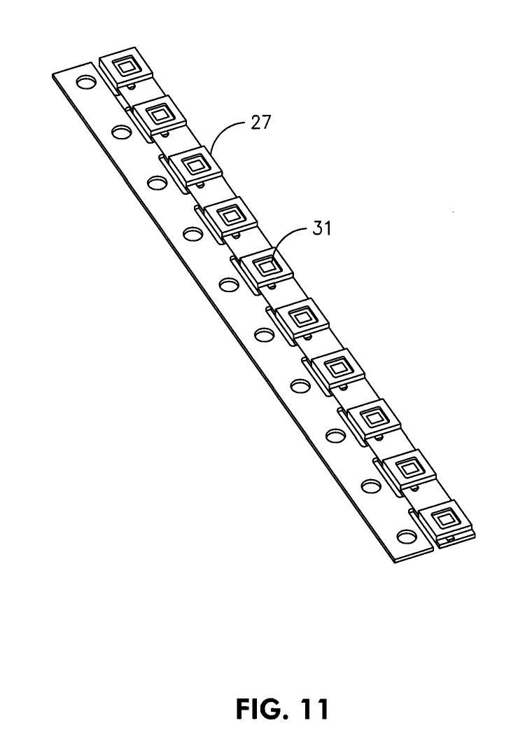

FIG. 11 shows multiple package tops placed onto the metal leadframe. If adhesive is used, the assembly can be heated to cure the adhesive. Or in the case where solder is used, the assembly can be heated to reflow the solder. In the alternative, the package top molded to the leadframe. Once this process is completed, the terminals 23, 24 are bonded to the package top.

While the assemblies are still connected to the leadframe a semiconductor die may be mounted into the opening in the package top 27. As noted above, a portion of terminal 23 is exposed by the cavity formed in the package top 27 forming a die contact pad 30. The die 31 can be die bonded to the larger terminal 23 with via an electrically conductive material such as solder. A wire 34 can then be bonded between the die and the die contact pad 30 and terminal 24. The cavity 29 can then be filled with a non-conductive molding material that protects the die. As shown in FIG. 12, the finished package assembly 33 can then singulated from the leadframe and tested.

Although features and elements are described above in particular combinations, each feature or element can be used alone without the other features and elements or in various combinations with or without other features and elements.

What is claimed is:

1. A package for an electronic component, the package comprising:
a metal base,
a termination chip coupled to the metal base, the termination chip including a die contact pad electrically coupled to a mounting pad and an isolating feature configured to provide electrical isolation between the metal base and the die contact pad, the die contact pad being configured for electrical connection to the electronic component.

2. The package of claim 1 wherein the metal base is folded to form a molding cavity.

3. The package of claim 1 comprising a metal strip formed with a molding cavity window, wherein the metal strip is stacked onto the metal base forming a molding cavity.

4. The package of claim 1 wherein a heat sinking feature is formed as an integral part of the package.

5. The package of claim 1 wherein the metal base includes at least one metalized layer.

6. The package of claim 1 further comprising a light emitting diode (LED) coupled to the metal base.

7. The package of claim 6 wherein the LED is coupled to the metal base via a eutectic bond.

8. The package of claim 6 further comprising an electrostatic discharge (ESD) protection device coupled to the metal base.

9. The package of claim 1 further comprising a plurality of angled die planes integrated into the metal base, the angled die planes being configured to mount a plurality of light emitting diodes.

10. The package of claim 1 wherein the termination chip further comprises a plurality of embedded circuit components.

11. A method of forming an electronic component package, the method comprising:
providing a metal base,
mounting a termination chip coupled to the meta base, the termination chip including a die contact pad electrically coupled to a mounting pad and an isolating feature configured to provide electrical isolation between the metal base and the die contact pad,
electrically connecting the electronic component to the die contact pad.

12. The method of claim 11 wherein the metal base is folded to form a molding cavity.

13. The method of claim 11 comprising stacking a metal strip formed with a molding cavity window onto the metal base, forming a molding cavity.

14. The method of claim 11 further comprising forming a heat sinking feature as an integral part of the package.

15. The method of claim 11 further comprising plating the metal base with at least one plating layer.

16. The method of claim 11 further comprising mounting a light emitting diode (LED) to the metal base.

17. The method of claim 16 further comprising coupling the LED to the metal base via a eutectic bond.

18. The method of claim 16 further comprising mounting an electrostatic discharge (ESD) protection device to the metal base.

19. The method of claim 11 further comprising forming a plurality of angled die planes integrated into the metal base, the angled die planes being configured to mount a plurality of light emitting diodes.

20. The method of claim 16 wherein the termination chip further comprises a plurality of embedded circuit components.

21. An electrical package for an electronic component, the package comprising:
a metal base having a first and second terminal, the first terminal having a die contact pad, the second terminal having a wire bonding pad;
a package top configured to locate and secure the terminals, the package top being formed with a cavity configured to expose the die contact pad and the wire bonding pad, the die contact pad being configured for electrical connection to the electronic component.

22. The package of claim 21 wherein the package top is formed with a raised portion and the metal base is formed with a slot dimensioned to accept the raised portion.

23. The package of claim 22 wherein the raised portion electrically isolates the first and second terminals.
